(19) United States
(12) Patent Application Publication
(10) Pub. No.: US 2018/0047564 A1
(43) Pub. Date: Feb. 15, 2018

(54) METHOD TO TUNE CONTACT CD AND REDUCE MASK COUNT BY TILTED ION BEAM

(71) Applicant: GLOBALFOUNDRIES, Inc., Grand Cayman (KY)

(72) Inventors: Chanro Park, Clifton Park, NY (US); Hoon Kim, Halfmoon, NY (US); Min Gyu Sung, Latham, NY (US); Ruilong Xie, Niskayuna, NY (US)

(21) Appl. No.: 15/233,445

(22) Filed: Aug. 10, 2016

(51) Int. Cl. H01L 21/027; H01L 21/306; H01L 21/263

(52) U.S. Cl. CPC H01L 21/0279; H01L 21/263; H01L 21/306

(57) ABSTRACT

A novel method of processing and fabricating semiconductor devices is provided to reduce critical dimensions inherent in a given photolithography process. A patterned mask layer generated via transfer of the pattern to the masking layer (e.g., printing) has a given set of dimensions. The method or process forms multiple layers beneath a masking layer. The multiple layers are etched to form openings therein according to the original mask pattern. Thereafter, one of the multiple layers is etched along its sidewalls to increase the opening therethrough, and this layer is utilized as the mask layer for the underlying semiconductor substrate. This enables a reduction in the critical dimensions, at least a critical dimension related to spacing between two features.

### TECHNICAL FIELD

The present disclosure relates generally to the manufacture of semiconductor devices, and more particularly, to the fabrication and manufacture of a semiconductor device using a method to reduce critical dimensions (CD) using a tilted ion beam process.

### BACKGROUND

In semiconductor processing technology, limitations inherent in the patterning or photolithography process result in certain critical dimensions (CDs). CDs are generally defined as the dimensions of the smallest geometrical features (line width, contact dimension, spacing, etc.) which can be formed during semiconductor device/circuit manufacturing using a given patterning or photolithography technology. For example, when a given pattern is transferred (or printed) onto a photoresist layer to create a masking layer for semiconductor processing, the printed features are generally spaced apart by at least the minimum CDs. This translates to certain limited dimensions (based on the CDs) for the structures to be formed on/in the semiconductor substrate.

It would be desirable to decrease CDs that result from a given patterning or photolithography process in order to decrease the minimum dimensions of the structures formed on/in the semiconductor substrate. Accordingly, there is a need for a new method or process that can control and reduce a given CD—which enables further reduction in feature dimensions.

### SUMMARY

In accordance with one advantageous embodiment, there is provided a method for semiconductor device processing. The method includes forming a multi-layer semiconductor stack, forming an optical layer above the semiconductor stack and having a first thickness, forming a first mask layer above the optical layer, and forming a second mask layer above the first mask layer. Portions of the second mask layer are selectively removing portions of the second mask layer to define a printed mask having openings therethrough and exposing corresponding portions of the first mask layer. Exposed portions of the first mask layer and corresponding portions of the optical layer are selectively removed according to the printed mask to expose corresponding portions of the semiconductor stack which generate substantially vertical sidewalls within the optical layer. At least one exposed portion of the semiconductor stack has an x dimension and a y dimension corresponding to dimensions of the printed mask. A tilted ion beam is directed towards at least one of the vertical sidewalls to remove a portion of one of the vertical sidewalls to form an angled sidewall which increases at least one of the x or y dimensions of the at least one exposed portion of the semiconductor substrate. The resulting optical layer forms a target mask. At least one exposed portion of the semiconductor stack is removed according to the target mask formed by the optical layer, the dimensions of the removed portion of semiconductor stack corresponding to the increased dimension of the target mask.

In another embodiment, there is provided a method of fabricating semiconductor devices. The method includes providing a multi-layer semiconductor substrate having a semiconductor stack, an optical layer disposed above the semiconductor stack having a first thickness, a first mask layer disposed above the optical layer, and a second mask layer disposed above the first mask layer. The method further includes selectively removing portions of the second mask layer to define a printed mask having openings therethrough and to expose portions of the first mask layer; selectively removing exposed portions of the first mask layer and the optical layer corresponding to the printed mask to expose portions of the semiconductor stack, the optical layer having openings therethrough with substantially vertical sidewalls; and selectively removing portions the substantially vertical sidewalls of the optical layer using a tilted ion beam to create a target mask that generates larger exposed portions of the semiconductor stack, at least one dimension of the larger exposed portions of the semiconductor stack having a corresponding dimension larger than the printed mask. The larger exposed portions of the semiconductor stack are etched or removed according to dimensions of the target mask.

In yet another embodiment, there is provided a method of generating a mask for use in fabricating semiconductor devices. The method includes forming an optical layer having a first thickness above a substrate; forming a first layer above the optical layer, and forming a masking layer above the first layer. Portions of the masking layer are selectively removed to define a printed mask having openings therethrough to expose portions of the first layer; exposed portions of the first layer and the optical layer corresponding to the printed mask are removed or etched to expose portions of the substrate, the optical layer has openings therethrough with substantially vertical sidewalls. The method further includes etching the substantially vertical sidewalls of the optical layer using an angled ion beam to form a target mask having at least one dimension larger than a dimension of the printed mask, and selectively removing exposed portions of the substrate according to the target mask.

The foregoing has outlined rather broadly the features and technical advantages of the present disclosure so that those skilled in the art may better understand the detailed description that follows. Additional features and advantages of the present disclosure will be described hereinafter that form the subject of the claims. Those skilled in the art should appreciate that they may readily use the concept and the specific embodiment(s) disclosed as a basis for modifying or designing other structures for carrying out the same or similar purposes of the present disclosure. Those skilled in the art should also realize that such equivalent constructions do not depart from the spirit and scope of the claimed invention in its broadest form.

Before undertaking the Detailed Description below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior uses, as well as future uses, of such defined words and phrases.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates an example of two printed features having a given CD therebetween and two corresponding target features with a reduced CD therebetween, in accordance with the present disclosure;

FIGS. 2-7 are diagrams that illustrate a series of steps of one embodiment of a method or process for reducing features/structures during manufacturing of semiconductor devices; and

FIG. 8 illustrates a relationship between thickness of a masking layer and ion beam angle in determining CD gain or feature enlargement.

### DETAILED DESCRIPTION

The present disclosure describes a novel method of processing and fabricating semiconductor devices by reducing critical dimensions inherent in a given photolithography process. A typical patterned mask layer is generated via transfer of the pattern to the masking layer (e.g., printing). The pattern features printed have a desired set of dimensions, and these dimensions are usually based on the minimum dimensions (critical dimensions) applicable to the given type of photolithography equipment (e.g., stepper, reticles, etc.) utilized. Thus, using the patterned mask, the physical dimensions of the deposited/formed structure(s) are limited to the critical dimensions attributable to the photolithography system. The present disclosure provides for a method or process to reduce one or more critical dimensions in the conventional masking and formation process. For example, when a pattern defines two separate features (e.g., two separate metal regions)—which would normally be separated by the critical dimension—the present process enables a reduction in the spacing between the features thereby allowing smaller features and line widths. This may be accomplished by forming a conventional mask on top of another layer and forming the other layer with a similar pattern to the conventional mask but which has increased dimensions (in at least one direction and/or axis)—resulting in a potential smaller spacing between two features. This does not necessarily reduce a given stucture's size, but allows denser placement of structures (e.g., closer together).

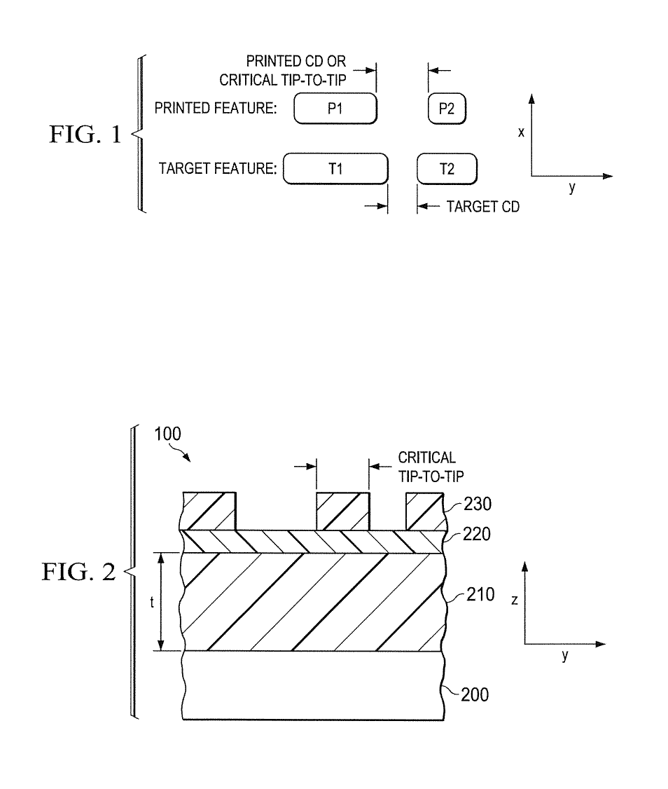

FIGS. 1 through 8 and the various embodiments used to describe the principles of the present disclosure in this patent document are by way of illustration only and should not be construed in any way to limit its scope. Those skilled in the art will understand that the principles described herein may be implemented in any type of suitably arranged process or method for fabricating semiconductor devices. To simplify the drawings, reference numerals from previous drawings will sometimes not be repeated for structures that have already been identified.

FIG. 1 provides an illustrative example of a printed feature pattern and a target feature pattern that will be utilized throughout this description to assist in explaining and understanding the present disclosure and its teachings. In this illustration, one may assume (for example) that the printed features will be two separate metal regions close to each other, but electrically separated (e.g., metal lines, contacts or vias) which are to be formed in an inter-level dielectric layer. As shown, the printed features are shown as P1 and P2 which are separated by the critical dimension referred to as the printed CD (PCD). The target features T1 and T2 correspond to P1 and P2, and the desired separation between T1 and T2 is referred to as the target CD (TCD). Because the photolithography equipment utilized is limited to printing P1 and P2 with a separation that is equal to or greater than the printed CD in conventional processing, the resulting structures will also be limited to that spacing. The present disclosure describes a method or process that utilizes an original mask formed with the printed feature pattern to create a second mask with the desired target feature pattern.

FIGS. 2 through 8 are diagrams that illustrate a series of relevant steps of one embodiment of a method or process for manufacturing or fabricating semiconductor devices.

Turning to FIG. 2, there is illustrated a cross-sectional view of a portion of a semiconductor substrate 100. The substrate 100 includes a semiconductor stack 200, an optical layer 210, a first masking layer of material 220 and a second masking layer of material 230. Also shown for illustrative purposes in the later Figures, are the corresponding printed feature pattern (shown in the top portion of the Figure) and target feature pattern (shown in the bottom portion of Figure). As will be appreciated, the second masking layer 230 is shown in FIG. 2 with the printed feature pattern (P1, P2) already formed therein, and formation of the layer 230 with its openings which correspond to the printed feature pattern (P1, P2) may be accomplished conventionally or using any other suitable process(es).

In one embodiment, the semiconductor stack 200 may include one or more of the following types and/or layers of materials or regions: substrate, inter-level dielectric, metal, source/drain regions, gate dielectric, gate stack, and the like, or other layers of material. Above the semiconductor stack 200, there is formed the optical layer 210 having a thickness t. The optical layer 210 may include, but is not limited to, carbon, amorphous carbon, or other layer or material containing carbon. In another embodiment, the optical layer 210 is formed of material susceptible to etching or removal via an ion beam—which may depend on the type and/or energy of ions utilized.

The first masking layer 220 is formed above the optical layer 210, as shown. The first masking layer 220 may be formed using an anti-reflective coating (ARC) material, such as an organic polymer-based layer or material, silicon oxynitride (SiON), Si-containing organic ARC (SiARC) or Ti-containing organic ARC (TiARC). One purpose of using anti-reflective material is to act as a light absorption layer to minimize reflection of light during lithography to form the openings in the second masking layer 230 (e.g., photoresist). Above the first masking layer 220 there is formed the second masking layer 230. As will be appreciated, the second masking layer 230 may be formed with conventional photoresist material and pattern etched via conventional processes.

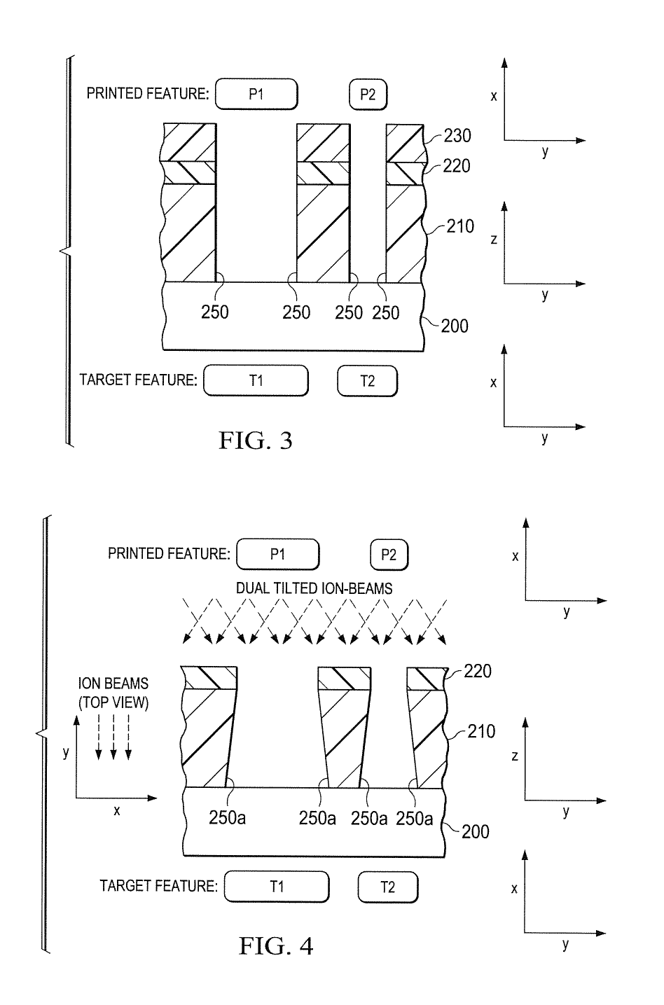

Now turning to FIG. 3, the structure shown in FIG. 2 undergoes an etch process which selectively removes portions of the first masking layer 220 and the optical layer 210. The etching process stops at the semiconductor stack 200 and exposes portions of the semiconductor stack 200 defined according to the printed feature pattern (of the second masking layer 230). Any suitable etching or removal process may be utilized. In one embodiment, the etching process is anisotropic which forms substantially vertical sidewalls 250 in the optical layer 210, as shown.

Now turning to FIG. 4, the structure shown in FIG. 3 undergoes another etch or removal process which selectively removes portions of the optical layer 210 along the vertical sidewalls. Etching/removal is accomplished using a tilted or angled ion beam. To enable enlargement of the optical layer 210 in one direction, such as they direction, the ion beam is directed only along the y direction and toward the sidewall(s) at an angle θ (in relation to the z axis). As will be appreciated, to enlarge in each y direction (+y, −y), a dual tilted or angled ion beam process is employed. It will also be understood that the mask enlargement process may also occur only in the x direction (and not the y direction). Further, the present disclosure may also be utilized to enlarge the mask (optical layer) in both the x and y directions using a quadruple tilted ion beam process.

This process generates angled sidewalls 250a in the optical layer 210. As will be appreciated, the resulting exposed portions of the semiconductor stack are larger than the corresponding openings through the masking layers 220/230 (the openings are configured with dimensions of P1 and P2, and the exposed portions of the stack 200 have dimensions of T1 and T2).

Any suitable ion beam etch process may be utilized, including oxygen or nitrogen combined with argon or helium. A halogen gas, such as chlorine, fluorine or bromine, can be added to the aforementioned ion beam.

Now turning to FIG. 8, there is provided a diagram illustrating how the mask enlargement depends, at least in part, on the ion beam angle and the thickness t of the optical layer 210. The amount of enlargement (in a given direction) is given by the equation: δ_{CD}=t*tan θ, as shown. Thus, the overall reduction in the spacing or CD between two features (in a given direction) equals two times this amount. As will be appreciated, changing the thickness t of the optical layer 210, the ion beam angle θ, or a combination thereof, will change the amount of enlargement δ_{CD}. Although this measurement is referred to as “CD gain” or enlargement, when viewed with respect to the spacing between the printed features P1 and P2, the spacing between the features is reduced, thus reducing the critical dimension of that spacing.

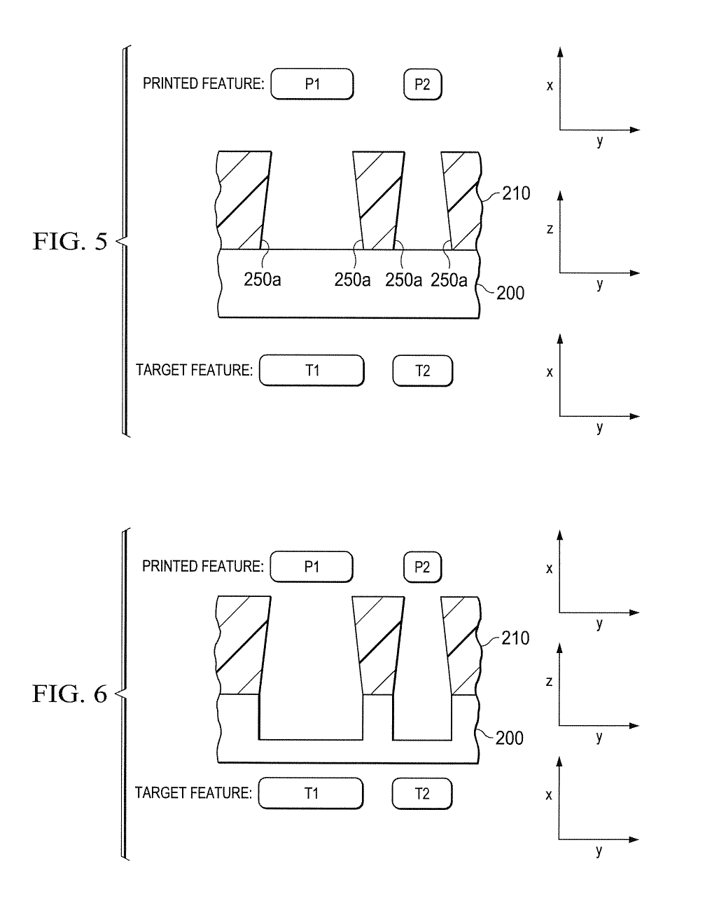

With reference to FIG. 5, the structure shown in FIG. 4 undergoes another suitable etch or removal process which removes either the remainder portions of the second masking layer 230, the remainder portions of the first masking layer 220, or both. This leaves the structure shown in FIG. 5 whereby the optical layer 210 now becomes the relevant mask for purposes of masking the semiconductor stack 200. It will also be appreciated that in an alternative embodiment, the second masking layer 230 may be removed prior to the ion beam etching process.

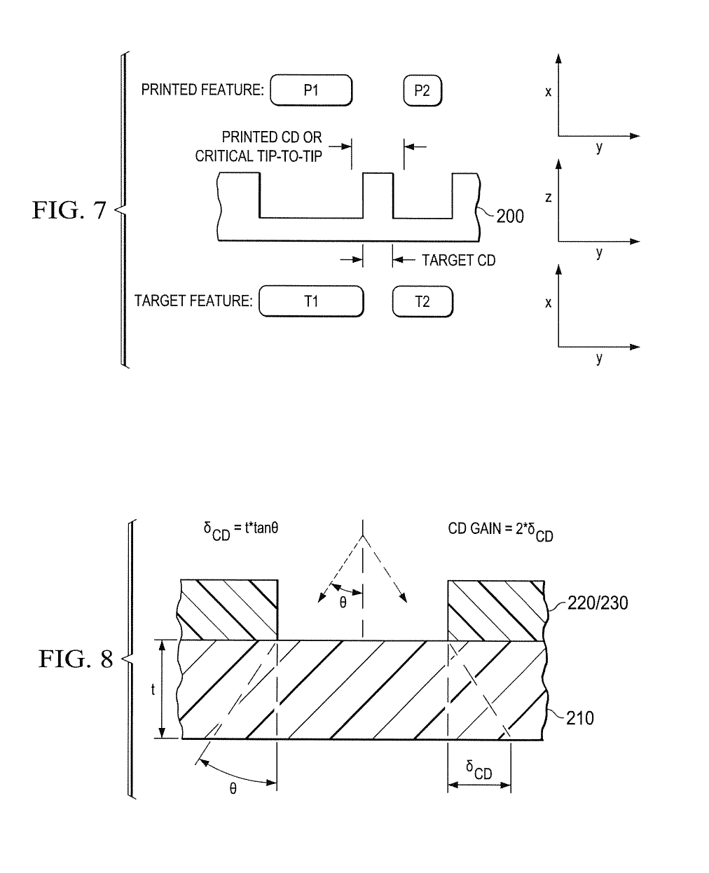

Now turning to FIG. 6, the structure shown in FIG. 5 undergoes a suitable etch process which selectively removes portions of the semiconductor stack 200 in accordance with the first masking layer 220. In FIG. 7, the remainder of the optical layer 210 (mask) is removed. This results in the structure shown in FIG. 7 having any etched pattern corresponding to the enlarged target feature pattern, yet having less spacing between the two features in the y direction (a reduction in CD spacing).

While FIG. 2-7 show relevant steps in one embodiment of forming semiconductor devices and processing, additional conventional/typical semiconductor manufacturing processes generally follow (which are not described herein, and is unnecessary for the understanding of the teachings herein). For example, metal deposition and planarization could be performed to the structure shown in FIG. 7 to generate metal conductor lines within the etched trenches.

It will be understood that well known processes have not been described in detail and have been omitted for brevity. Although specific steps, structures and materials may have been described, the present disclosure may not limited to these specifics, and others may substituted as is well understood by those skilled in the art, and various steps may not necessarily be performed in the sequences shown.

It will be understood that the present disclosure may be embodied in many different forms and should not be construed as limited to the exemplary embodiments set forth herein. Terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The terms “comprises” and/or “comprising”, or “includes” and/or “including”, when used in this specification, specify the presence of stated features, regions, structures, elements, and/or components, but do not preclude the presence or addition of one or more other of these. Reference throughout this specification to “one embodiment,” “an embodiment,” “embodiments,” “exemplary embodiments,” or similar language means that a particular feature, structure, or characteristic described in connection with the embodiment is included in at least one embodiment of the present disclosure.

If used, the terms “overlying” or “atop”, “positioned on” or “positioned atop”, “underlying”, “beneath” or “below” mean that a first element, such as a first structure, e.g., a first layer, is present on a second element, such as a second structure, e.g., a second layer, wherein intervening elements, such as an interface structure, e.g. interface layer, may be present between the first element and the second element.

As used herein, “depositing” or “forming” may include any now known or later developed techniques appropriate for the material to be deposited or formed including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UH-VCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer 20 deposition (ALD), chemical oxidation, molecular beam epitaxy (MBE), plating, evaporation.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

1. A method of semiconductor device processing, the method comprising:
forming a multi-layer semiconductor stack;
forming an optical layer above the semiconductor stack and having a first thickness;
forming a first mask layer above the optical layer, and
forming a second mask layer above the first mask layer;
selectively removing portions of the second mask layer to define a printed mask having openings therethrough and exposing corresponding portions of the first mask layer;
selectively removing the exposed portions of the first mask layer and corresponding portions of the optical layer according to the printed mask to expose corresponding portions of the semiconductor stack and generating substantially vertical sidewalls within the optical layer, at least one exposed portion of the semiconductor stack having an x dimension and a y dimension corresponding to dimensions of the printed mask;
directing a tilted ion beam towards at least one of the vertical sidewalls and removing a portion of one of the vertical sidewalls to form an angled sidewall to increase at least one of the x or y dimensions of at least one exposed portion of the semiconductor substrate, the resulting optical layer forming a target mask; and
selectively removing at least one exposed portion of the semiconductor stack according to the target mask formed by the optical layer, the dimensions of the removed portion of semiconductor stack corresponding to the increased dimension of the target mask.

2. The method in accordance with claim 1 wherein:
the first mask layer comprises an anti-reflective material; and
the optical layer comprises optical material etchable by the tilted ion beam.

3. The method in accordance with claim 2 wherein the thickness of the second mask layer and an angle of the tilted ion beam at least in part determine the increase in the x or y dimension of the exposed portion of the semiconductor stack.

4. The method in accordance with claim 3 wherein the first mask layer comprises an organic polymer-based material.

5. The method in accordance with claim 4 wherein the optical layer comprises carbon.

6. The method in accordance with claim 1 wherein:
the second mask layer comprises photoresist material; and
the first mask layer is configured to reduce reflection of light when forming openings in the second mask layer.

7. The method in accordance with claim 6 wherein the first mask layer comprises an organic polymer-based material.

8. The method in accordance with claim 7 wherein the optical layer comprises carbon.

9. The method in accordance with claim 1 wherein directing a tilted ion beam towards at least one of the vertical sidewalls and removing a portion of one of the vertical sidewalls to form an angled sidewall to increase at least one of the x or y dimensions of at least one exposed portion of the semiconductor substrate, the resulting optical layer forming a target mask, comprises:
directing a first tilted ion beam towards a first one of the vertical sidewalls and removing a portion of the first one of the vertical sidewalls to form an angled sidewall to increase a first direction of at least one exposed portion of the semiconductor substrate; and
directing a second tilted ion beam towards a second one of the vertical sidewalls and removing a portion of the second one of the vertical sidewalls to form an angled sidewall to increase an opposite direction of at least one exposed portion of the semiconductor substrate.

10. A method of fabricating semiconductor devices, the method comprising:
providing a multi-layer semiconductor substrate, comprising,
a semiconductor stack,
an optical layer disposed above the semiconductor stack having a first thickness,
a first mask layer disposed above the optical layer, and
a second mask layer disposed above the first mask layer;
selectively removing portions of the second mask layer to define a printed mask having openings therethrough and to expose portions of the first mask layer;
selectively removing exposed portions of the first mask layer and the optical layer corresponding to the printed mask to expose portions of the semiconductor stack, the optical layer having openings therethrough with substantially vertical sidewalls;
selectively removing portions of the substantially vertical sidewalls of the optical layer using a tilted ion beam to create a target mask that generates larger exposed portions of the semiconductor stack, at least one dimension of the larger exposed portions of the semiconductor stack having a corresponding dimension larger than the printed mask; and
selectively removing the larger exposed portions of the semiconductor stack according to dimensions of the target mask.

11. The method in accordance with claim 10 wherein:
the first mask layer comprises an anti-reflective material; and
the optical layer comprises optical material etchable by the tilted ion beam.

12. The method in accordance with claim 11 wherein the thickness of the second mask layer and an angle of the tilted ion beam at least in part determine in at least one dimension of the exposed semiconductor stack.

13. The method in accordance with claim 12 wherein:
the first mask layer comprises an organic polymer-based material; and
the optical layer comprises carbon.

14. The method in accordance with claim 10 wherein:
the second mask layer comprises photoresist material; and
the first mask layer is configured to reduce reflection of light when forming openings in the second mask layer.

15. The method in accordance with claim 14 wherein:
the first mask layer comprises an organic polymer-based material; and
the optical layer comprises carbon.

16. The method in accordance with claim 10 wherein selectively removing portions of the substantially vertical sidewalls of the optical layer using a tilted ion beam to create a target mask that generates larger exposed portions of the semiconductor stack, at least one dimension of the larger exposed portions of the semiconductor stack having a corresponding dimension larger than the printed mask, comprises:
directing a first tilted ion beam at a first angle towards a first one of the substantially vertical sidewalls and removing a portion to form a first angled sidewall to increase in a first direction the at least one dimension of at least one exposed portion of the semiconductor substrate; and
directing a second tilted ion beam at a second angle towards a second one of the substantially vertical sidewalls and removing a portion to form a second angled sidewall to increase in a direction opposite to the first direction the at least one dimension of at least one exposed portion of the semiconductor substrate.

17. The method in accordance with claim 16 wherein the first angle and the second angle are substantially equal in degrees in relation to the substantially vertical sidewalls.

18. A method of generating a mask for use in fabricating semiconductor devices, the method comprising:
forming an optical layer having a first thickness above a substrate;
forming a first layer above the optical layer, and
forming a masking layer above the first layer;
selectively removing portions of the masking layer to define a printed mask having openings therethrough to expose portions of the first layer;
selectively removing exposed portions of the first layer and the optical layer corresponding to the printed mask to expose portions of the substrate, the optical layer having openings therethrough with substantially vertical sidewalls;
etching the substantially vertical sidewalls of the optical layer using an angled ion beam to form a target mask having at least one dimension larger than a dimension of the printed mask; and
selectively removing exposed portions of the substrate according to the target mask.

19. The method in accordance with claim 18 wherein:
the first layer comprises an anti-reflective material; and
the optical layer comprises optical material etchable by the tilted ion beam.

20. The method in accordance with claim 18 wherein the thickness of the optical layer and an angle of the angled ion beam at least in part determine the at least one dimension larger than a dimension of the printed mask.
